(19) United States
(12) Patent Application Publication
(10) Pub. No.: US 2024/0332057 A1
(43) Pub. Date: Oct. 3, 2024

(54) METHOD AND SYSTEM FOR MANIPULATING A MICROMETRIC DEVICE

(71) Applicant: ALEDIA, Échirolles (FR)

(72) Inventors: Hugues LEBRUN, Coublevie (FR); Frédéric MAYER, Moirans (FR)

(73) Assignee: ALEDIA, Échirolles (FR)

(21) Appl. No.: 18/618,436

(22) Filed: Mar. 27, 2024

(30) Foreign Application Priority Data
Mar. 29, 2023 (FR) 23/03030

(51) Int. Cl. H01L 21/683; H01L 21/66; H01L 21/67; H01L 25/075

(52) U.S. Cl. CPC H01L 21/6838; H01L 21/67144; H01L 22/20; H01L 25/0753

(57) ABSTRACT

A manipulation system intended to manipulate micrometric devices, the manipulation system including a main body internally delimiting a suction chamber, suction nozzles including a suction channel emerging on the one hand towards the suction chamber, and on the other hand at a gripping end intended to be brought into contact with a micrometric device; shutter elements, configured to shut off a suction nozzle so as to prevent the gripping of a micrometric device or to allow a fluid communication between a gripping opening of the gripping end and the suction chamber, so as to allow the gripping of a micrometric device in contact with said gripping end. A manipulation method for manipulating micrometric devices by such a manipulation system.

### TECHNICAL FIELD OF THE INVENTION

The present invention concerns a system for manipulating at least one micrometric device, and in particular at least one electronic device.

The invention also concerns a method for manipulating such a micrometric device.

### STATE OF THE ART

In the field of luminous display screens, the luminous elements constituting the screen must be arranged in matrix fashion in an increasingly precise manner as the resolution of the screens increases. Furthermore, for a given screen size, this increase in the resolution is accompanied by an increase in the number of luminous elements having increasingly smaller sizes. These luminous elements each comprise at least one light-emitting diode and are organized, for example, in the form of a multi-colored pixel or in the form of a monochrome sub-pixel.

It is known to produce the light-emitting diodes on an initial support in the form of a silicon or sapphire substrate and to transfer them, for example by compression or even thermocompression, onto a receiving support different from the initial support and intended to constitute, after this transfer by pressure or thermocompression, the luminous display screen.

Thus, in the field of luminous display screens and more generally in the field of microelectronics or nanotechnologies, there is a need to transfer a large quantity of electronic devices which have increasingly small sizes.

For example, in the particular case of light-emitting diodes, a critical step of manufacturing screens is to manage to transfer a large quantity of light-emitting diodes between the initial support on which the light-emitting diodes are formed or manufactured, and the final screen substrate. Furthermore, light-emitting diodes may be naturally damaged in the general manufacturing process. The mass transfer therefore sometimes involves the transfer of previously defective light-emitting diodes which are deposited on the screen and constitute black spots on the final device.

To try to resolve this problem, it is possible to make a repair or a change of the defective light-emitting diodes. Although this method makes it possible to reduce the number of black spots, it involves additional manufacturing steps, which may increase costs and is tedious to implement. Another solution consists in creating redundancy areas, that is to say areas in which a functional diode is added near a defective diode. Although this solution is satisfactory in that it limits the number of black spots, it remains expensive to implement.

Another method called “pick and place”, consists in displacing the light-emitting diodes individually, thus making it possible to select and transfer only light-emitting diodes which we are sure are functional. This has the advantage of avoiding the need for a step of replacing defective transferred diodes. Although this second method is satisfactory in that it avoids the formation of black spots, it has the disadvantage of being very slow to implement, and therefore generates significant costs which are prohibitive in the case of the mass transfer of light-emitting diodes.

If the above problems have been previously exposed in connection with the particular case of light-emitting diodes, similar or close problems may be present in the case of other electronic devices which are to be transferred, such as for example vertical-external-cavity surface-emitting-laser (or VECSEL), photodiodes, piezoelectric micromachined ultrasonic transducers (or PMUT), capacitive micromachined ultrasonic transducers (or CMUT), or even light boxes.

The devices to be transferred may also correspond to non-active constituent elements of electronic devices, such as for example polymer pellets taken from a pre-cut film to be deposited only on certain electronic devices of a final substrate. Such a specific optical film pellet formed selectively may in particular serve as a color converter, and to improve the luminosity, to filter or locally compensate the wavelengths, etc.

The micrometric, optoelectronic, electronic or non-electronic device to be manipulated typically has a size comprised between 5 micrometers and 500 micrometers.

It is also known from document US2020/0258767, a method making it possible to carry out the transfer of a large quantity of electronic devices by securing said electronic devices to nozzles. In this method, a reduced pressure is applied to the nozzles so that they may suck up the electronic devices to be transferred. For this, a transfer member is provided with a matrix of nozzles, the nozzles being spaced apart from each other according to the same spacing as that separating the electronic devices to be transferred, and corresponding to the pitch of the pixels on the screen. However, although this method makes it possible to simply displace a large number of electronic devices while limiting their damage, it is unfortunately not possible to carry out a selective transfer of the electronic devices, which does not prevent the transfer of electronic devices which would be defective.

### Object of the Invention

The present invention aims to propose a solution which responds to all or part of the aforementioned problems.

This aim may be achieved by implementing a manipulation system intended to manipulate a plurality of micrometric devices, the manipulation system comprising:
a main body internally delimiting a suction chamber, said suction chamber being intended to be in fluid communication with a pressure reduction device;
a manipulation unit comprising a plurality of suction nozzles, each suction nozzle of the plurality of suction nozzles comprising a suction channel emerging on the one hand towards the suction chamber at a suction opening, and on the other hand at a gripping end intended to be brought into contact with a micrometric device of the plurality of micrometric devices;
a shutter unit comprising a plurality of shutter elements, each shutter element being configured to cooperate with a suction nozzle of the plurality of suction nozzles, and being configured to vary between a release configuration in which the shutter element shuts off the suction nozzle so as to prevent the gripping of a micrometric device in contact with said gripping end, and a gripping configuration in which the shutter element allows a fluid communication between a gripping opening of the gripping end and the suction chamber, so as to allow the gripping of a micrometric device in contact with said gripping end,
the shutter unit further comprising an actuation unit comprising a plurality of displacement actuators, wherein each displacement actuator is configured to selectively vary at least one of the shutter elements between the gripping configuration and the release configuration.

The arrangements previously described make it possible to propose a manipulation system in which each shutter element may be selectively monitored in order to allow or prevent the securing of a micrometric device to a suction nozzle. It is thus possible to selectively take a plurality of micrometric devices by the manipulation system, for example to perform a selective mass transfer of micrometric devices.

It is well understood that when a shutter element is in the gripping configuration, a micrometric device in contact with the gripping end of the gripping nozzle associated with said shutter element is maintained in contact with said gripping end by suction. Said suction being guaranteed by the application of a reduced pressure to the suction chamber by the pressure reduction device, said reduced pressure then also being applied to each suction nozzle communicating with the suction chamber.

The manipulation system may also have one or more of the following characteristics, taken alone or in combination.

According to one embodiment, the shutter element completely shuts off the suction nozzle in the release configuration. Alternatively, the release configuration may correspond to a partial shuttering of the suction nozzle by the shutter element.

According to one embodiment, each displacement actuator is a microelectromechanical system, or MEMS.

According to one embodiment, each shutter element is a microelectromechanical system, or MEMS.

According to one embodiment, the manipulation system comprises a control unit comprising a plurality of electronic control circuits, said control unit being offset relative to the manipulation unit.

It is therefore clearly understood that according to this embodiment, the control unit and the manipulation unit are two distinct and independent parts.

In this way, the control unit may be manufactured without requiring the presence of orifices for fluid communication between the suction nozzles and the suction chamber, which would have made its design impossible or very complex. A control unit carried out in a way that it can be separated and offset from the manipulation unit may then be designed as a durable element of the manipulation system, unlike the manipulation unit which may be used as a consumable.

According to one embodiment, each displacement actuator and/or shutter element is associated with an electronic control circuit.

According to one embodiment, the micrometric devices to be manipulated comprise electronic devices, typically optoelectronic devices.

By “micrometric device” is meant a device comprising a largest dimension less than one millimeter, typically comprised between 5 micrometers and 500 micrometers.

According to one embodiment, the displacement actuator and/or the shutter element comprises an electronic control circuit.

According to one embodiment, each shutter element, and/or each displacement actuator may be individually controlled by the electronic control circuit with which it is associated. For example, this command may be carried out depending on the matrix distribution of the displacement actuators and/or of the shutter elements. Each displacement actuator and/or each shutter element may then be configured to receive an electrical signal coming from the electronic control circuit with which it is associated to cause the variation of said shutter element between the gripping configuration and the release configuration according to said electrical signal. It is thus possible to send an electrical signal per line and/or per column to control selectively and in matrix fashion the shutter elements and/or the displacement actuators.

According to one embodiment, each electronic control circuit may comprise at least one transistor. For example, each electronic control circuit may comprise a control transistor configured to be switched so as to authorize or alternatively prevent a passage of electric current, said electric current then inducing a change of configuration between the gripping configuration and the release configuration. The electronic control circuit may also comprise a selection transistor configured to receive row and column instructions coming from a matrix control unit, to switch or not the control transistor depending on the instructions received. Thus, the selection transistor makes it possible to monitor the switching state of the control transistor independently of the other selection transistors disposed on the same line or on the same column.

According to one embodiment, an opening area of the gripping opening of each suction nozzle is strictly less than a contact surface of a micrometric device intended to be manipulated by the manipulation system.

According to one embodiment, a largest dimension of an opening area of the gripping opening is strictly less than 1 mm.

In this way, when the micrometric device is engaged with the suction nozzle, it is maintained by suction on the surface of the manipulation unit.

According to one embodiment, at least one shutter element of the plurality of shutter elements comprises at least one displacement actuator of the plurality of displacement actuators.

In other words, each shutter element may form a displacement actuator and vice versa.

According to one embodiment, the shutter elements are activated individually and/or selectively by the displacement actuators.

According to one embodiment, the shutter element and/or the displacement actuator comprises an elastically deformable blade, configured to vary between two distinct spatial configurations, one being naturally occupied by elastic return of the material and the other being temporarily occupied under the action of an external force, typically of a mechanical, electrostatic, thermal, electromagnetic nature or any other method. Alternatively, the curved configuration may be naturally occupied by elastic return of the material, and the planar configuration may be temporarily occupied under the action of an external force, typically of a mechanical, electrostatic, thermal, electromagnetic nature or any other method.

According to one embodiment, at least one shutter element comprises a flexible membrane.

Advantageously, a membrane has a thickness strictly smaller than a piston. It is therefore less bulky than a rigid shutter element, as may be a piston, it may therefore be more easily integrated into a micrometric system. In addition, a membrane may be carried out with a wide variety of materials chosen depending on the integration needs. A membrane therefore has great ease of integration, as opposed to a piston which induces constraints on its integration.

In this way, it is possible to simply vary the flexible membrane between the release configuration and the gripping configuration. For example, the flexible membrane may comprise a deformable portion configured to be deformed under the direct or indirect action of the displacement actuator.

According to one embodiment, at least one of the shutter elements comprises a cooperation portion having a frustoconical shape, said cooperation portion being configured to cooperate with the suction opening of one of the suction nozzles, when said at least one shutter element comprising the cooperation portion occupies the release configuration.

In this way, it is possible to displace the cooperation portion to shut off the suction nozzle, particularly when the suction opening has a circular cross section.

According to one embodiment, at least one of the displacement actuators is configured to selectively vary at least one of the shutter elements between the gripping configuration and the release configuration by electrostatic or magnetic interaction.

For example, said at least one displacement actuator may comprise a conductive electrode, or a piezoelectric actuator.

According to one embodiment, at least one of the displacement actuators is a micrometric electromechanical system, or MEMS for microelectromechanical system.

For example, the implementation of an electrostatic interaction may consist in imposing a difference in electric potential between two electrodes, generally disposed opposite each other. The electric field thus creates a force which tends to cause the electrodes to move towards each other. For example, one of the electrodes may be a floating electrode, maintained by a flexible electrical conductor, such as a flexible membrane. This floating electrode may then be brought closer to another neighboring electrode, in particular when an electric field is applied between the two electrodes.

According to one embodiment, the implementation of a magnetic interaction may consist in causing the displacement of two objects under the application of a magnetic field between these two objects, and by exploiting the Lorentz force thus generated to carry out this displacement.

According to one embodiment, the manipulation system comprises a guide support comprising a plurality of guide conduits provided in the guide support, each guide conduit being configured to guide a linking element along a guide direction for directly or indirectly cause a variation of one of the shutter elements between the release configuration and the gripping configuration.

According to one embodiment, the control unit is disposed on the side opposite the manipulation unit relative to the guide support.

According to one embodiment, a linking element is associated with each electronic control circuit, said linking element forming a link from the control unit to the manipulation unit between a suction nozzle and the electronic control circuit with which it is associated.

According to one embodiment, the linking element comprises a non-mobile electrical connection, such as a wired connection, said linking element ensuring an electrical connection between an electronic control circuit and a displacement actuator. This is particularly advantageous in the case where the electronic control circuit acts as a switch to actuate or not a displacement actuator.

According to one embodiment, the shutter element comprises the linking element, each guide conduit then being disposed opposite one of the suction nozzles, and configured to guide the shutter element along the guide direction when said shutter element varies between the release configuration and the gripping configuration.

According to one embodiment, each shutter element extends between an actuation end, and a shutter end configured to cooperate with the suction opening of one of the suction nozzles.

According to one embodiment, the linking element extends between a monitoring end configured to cooperate with an electronic control circuit, preferably through a switching agent, and a control end configured to cooperate with a displacement actuator.

According to one embodiment, each guide conduit may be offset relative to the suction nozzles, each guide conduit being configured to guide one of the linking elements along the guide direction when said linking element is actuated so as to cause a variation of one of the shutter elements between the release configuration and the gripping configuration.

It is therefore well understood that the linking elements make it possible to relocate the electronic control circuits and possibly the displacement actuators on a support separated from and spaced apart from the manipulation unit including the suction nozzles. The control unit may thus be a solid support, without orifice, allowing to carry out the electronic control circuits, and possibly the displacement actuators, while allowing to carry out a suction chamber in fluid communication with each of the suction nozzles of the manipulation unit. It is thus possible to replace the displacement actuators, and/or the electronic control circuits, independently of the manipulation unit and of the suction nozzles. In other words, the control unit and the manipulation unit may be replaced or manufactured independently of each other. Synergistically, the guide support allows to facilitate the design and allows a reliable guidance of the linking elements in the guide conduits, particularly if they are mobile in translation.

This is particularly advantageous when manufacturing the manipulation system, because it is possible to separately manufacture the manipulation unit which comprises the suction nozzles intended to be in contact with the micrometric devices, and the control unit which comprises the electronic control circuits and possibly the displacement actuators. Indeed, the manufacturing of the manipulation unit is made complex by the number and the shape of the manipulation nozzles which constitute wearing parts of the manipulation system. Conversely, the control unit comprises the electronic control circuits whose manufacturing cost may be higher, but whose wear is slower because they do not come into contact with other parts.

In this way, it is possible to provide a manipulation system in which the distribution of the guide conduits corresponds to the distribution of the suction nozzles.

According to one embodiment, each guide conduit is configured to guide the shutter elements in translation along the guide direction.

According to one embodiment, the guide support is disposed in the suction chamber, for example between the displacement actuators and the suction nozzles.

According to one embodiment, the guide support forms at least partially a wall of the suction chamber.

According to one embodiment, each shutter element comprises a shutter rod mobile in translation in a guide conduit of the plurality of guide conduits, said shutter rod extending between an actuating end and a shutter end configured to cooperate with the suction opening of one of the suction nozzles.

According to one embodiment, the actuating end of the shutter rod is configured to cooperate with one of the displacement actuators.

In this way, the actuation of the shutter elements is performed at an end opposite to that where the shuttering of the suction nozzles is performed, it is therefore possible to independently repair or replace the manipulation unit and the shutter unit.

According to one embodiment, the shutter element is fastened to the displacement actuator. For example, the shutter element may be in the release configuration in a rest position in which no actuation is implemented by the displacement actuator, and may vary in the gripping configuration when the displacement actuator is actuated.

Alternatively, the shutter element may be in the gripping configuration in a rest position in which no actuation is implemented by the displacement actuator, and may vary in the release configuration when the displacement actuator is actuated.

According to one embodiment:
the suction nozzles of the manipulation unit are disposed according to a first matrix distribution defined by at least one first lattice parameter,
the shutter elements of the shutter unit are disposed according to a second matrix distribution defined by at least one second lattice parameter;
   one of the first lattice parameter and of the second lattice parameter being an integer multiple of the other.

According to one embodiment, the displacement actuators of the actuation unit are disposed according to a third matrix distribution defined by at least one third lattice parameter, the first lattice parameter, the second lattice parameter, and the third lattice parameter being integer multiples of each other.

According to one embodiment, the displacement actuators are disposed according to a third matrix distribution defined by at least one third lattice parameter which is an integer multiple of the second lattice parameter, the manipulation system further comprising a control unit comprising a plurality of electronic control circuits distributed according to a fourth matrix distribution defined by at least one fourth lattice parameter which is an integer multiple of the third lattice parameter, each displacement actuator being associated with an electronic control circuit and configured to receive an electrical signal coming from the electronic control circuit with which it is associated to cause the variation of said shutter element between the gripping configuration and the release configuration depending on said electrical signal.

According to one embodiment, the first lattice parameter is equal to the second lattice parameter, and/or to the third lattice parameter.

Thus, the manipulation system may advantageously be used to manipulate micrometric devices disposed according to a matrix distribution on a sampling substrate.

The aim of the invention may also be achieved by implementing a method for manipulating a plurality of micrometric devices where each micrometric device has a contact surface, the manipulation method comprising:
a provisioning phase in which a manipulation system of the type of one of those described above is provided, the gripping end of at least one of the suction nozzles being in contact with the contact surface of at least one of said micrometric devices;
an actuation phase in which at least one of the shutter elements cooperating with one of the suction nozzles in contact with one of the micrometric devices is varied between the gripping configuration and the release configuration, the actuation phase then comprising, for at least one of the configuration-varying shutter elements, chosen from said at least one of the shutter elements:
   a securing step in which the micrometric device is secured to the suction nozzle when said configuration-varying shutter element is varied to the gripping configuration, or
   a separation step in which the micrometric device is separated from the suction nozzle when said configuration-varying shutter element is varied to the release configuration.

It is therefore well understood that the securing step may be implemented when a shutter element is varied to, or is in the gripping configuration. It is also well understood that the separation step may be implemented when a shutter element is varied to, or is in the release configuration.

The arrangements previously described make it possible to propose a manipulation method in which micrometric devices may be attached or detached from the manipulation system by selective actuation of the displacement actuators. This makes it possible to selectively manipulate a large quantity of micrometric devices, by a single method step, and through a single manipulation system.

The manipulation method may also have one or more of the following characteristics, taken alone or in combination.

According to one embodiment, the provisioning phase comprises:
a step of providing the manipulation system of the type of one of those described above;
a step of providing the plurality of micrometric devices disposed on a sampling substrate;
a contacting step, in which the gripping end of at least one of the suction nozzles is brought into contact with the contact surface of at least one of the micrometric devices.

Thus, the provisioning phase may be implemented in order to take one or more micrometric devices from the surface of a sampling substrate, for example in order to transfer them.

According to one embodiment, the manipulation method comprises an unhooking step implemented after the actuation phase, in which the manipulation system is moved away from the sampling substrate, so as to unhook, relative to the sampling substrate, the micrometric devices secured to suction nozzles during the securing step.

In this way it is possible to selectively collect the micrometric devices to be manipulated from the surface of the sampling substrate.

According to one embodiment, the unhooking step is implemented by mechanical traction.

According to one embodiment, the actuation phase is implemented when at least one of the displacement actuators of the actuation unit is actuated, so as to cause the variation of at least one of the shutter elements cooperating with one of the suction nozzles in contact with one of the micrometric devices between the gripping configuration and the release configuration.

According to one embodiment, the actuation phase is implemented by a magnetic or electrostatic actuation of at least one of the displacement actuators.

According to one embodiment, the actuation phase is implemented by a thermal or mechanical actuation of the at least one displacement actuator.

According to one embodiment, the manipulation method comprises a transfer step implemented after the provisioning phase, in which the manipulation system is placed opposite a receiving support capable of receiving at least one of the manipulated micrometric devices.

In this way it is possible to place the micrometric devices opposite a receiving surface of the receiving support which can be the final destination support of the micrometric devices. In the case where the micrometric devices are optoelectronic devices, the transfer step may be implemented so as to place the optoelectronic devices facing a screen substrate.

According to one embodiment, the manipulation method comprises an alignment step in which the manipulation system is aligned with the receiving support. In this way, it is possible to precisely determine the location at which each micrometric device may be deposited on the receiving support. For example, in the case of manipulating electronic devices, the alignment step may be implemented so as to align each electronic device with electrically conductive elements disposed on the receiving support and configured to supply the electronic devices with electrical energy.

According to one embodiment, the manipulation method comprises a deposition step, implemented after the transfer step, in which the manipulation system is brought close to the receiving support, so as to directly or indirectly bring into contact, manipulated micrometric devices, with said final receiving support. For example, in the case of manipulating electronic devices, each electronic device is brought into contact with the electrically conductive elements.

According to one embodiment, the manipulation method comprises a removal step, implemented after the deposition step, in which the manipulation system is moved away from the receiving support.

According to one embodiment, at least one of the micrometric devices to be manipulated is an electronic device, the manipulation method comprising a test step in which said at least one electronic device is electrically tested in order to determine whether it is functional or non-functional, the actuation phase then being implemented depending on the result of the test step.

In this way, depending on the destination of the electronic devices it is possible to adapt the actuation phase.

According to one embodiment, the actuation phase is applied selectively so as to implement the securing step for the functional electronic devices, and so as to implement the separation step for the non-functional electronic devices.

In this way, it is possible to pick up and possibly displace the functional devices, for example to transfer them to a final receiving support.

According to another embodiment, the actuation phase is applied selectively so as to implement the separation step for the functional electronic devices, and so as to implement the securing step for the non-functional electronic devices.

In this way, it is possible to pick up and possibly displace the non-functional devices, for example to remove them from a final receiving substrate, or from a sampling substrate before performing a non-selective mass transfer of the functional devices remaining on the surface of the sampling substrate.

### SUMMARY DESCRIPTION OF THE DRAWINGS

Other aspects, aims, advantages and characteristics of the invention will appear better on reading the following detailed description of preferred embodiments thereof, given by way of non-limiting example, and made with reference to the appended drawings on which:

FIG. 1 is a schematic view of a manipulation system according to a first embodiment of the invention.

FIG. 2 is a schematic view of a manipulation system according to a second embodiment of the invention.

FIG. 3 is a schematic view of certain elements of a manipulation system according to a third embodiment of the invention.

FIG. 4 is a schematic view of certain steps of the manipulation method according to a particular embodiment of the invention.

FIG. 5 is a schematic view of certain steps of the manipulation method according to a particular embodiment of the invention.

FIG. 6 is a schematic view of certain steps of the manipulation method according to a particular embodiment of the invention.

### DETAILED DESCRIPTION

On the figures and in the remainder of the description, the same references represent the identical or similar elements. In addition, the different elements are not represented to scale so as to favor the clarity of the figures. Furthermore, the different embodiments and variants are not exclusive of each other and may be combined with each other.

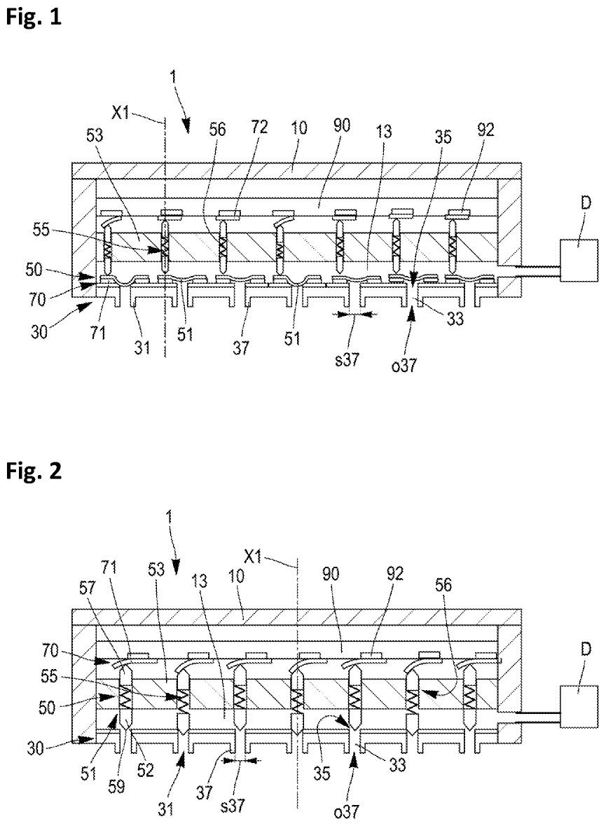

As illustrated on FIGS. 1 and 2, the invention concerns a manipulation system 1 intended to manipulate micrometric devices 3. As will be described later with reference to the manipulation method, the micrometric devices 3 may be disposed, before manipulation, on a sampling support 2, and comprise a contact surface s3. Generally speaking, the terms “micrometric device” mean a device comprising a largest dimension less than one millimeter, and typically comprised between 5 micrometers and 500 micrometers. Without this being limiting, it may be envisaged that each micrometric device 3 is an electronic device, or an optoelectronic device. Thus, the manipulation system is suitable for the mass transfer of optoelectronic devices, for example in a method for manufacturing display screens.

The manipulation system 1 comprises a main body 10 internally delimiting a suction chamber 13, said suction chamber 13 being intended to be in fluid communication with a pressure reduction device denoted “D”, external to the manipulation system 1. This pressure reduction system D is configured to place the suction chamber 13 in reduced pressure relative to the pressure prevailing outside the manipulation system 1.

FIGS. 1 and 2 illustrate two distinct embodiments of the invention, but which may both be used to implement the manipulation method which will be described below. The manipulation system 1 of these two figures comprises a manipulation unit 30 comprising a plurality of suction nozzles 31; a shutter unit 50 comprising a plurality of shutter elements 51, and which comprises an actuation unit 70 comprising a plurality of displacement actuators 71. The manipulation system 1 may also comprise a control unit 90 comprising a plurality of electronic control circuits 92, which may be offset relative to the manipulation unit 30. It is therefore well understood that the control unit 90 and the manipulation unit 30 may be two distinct and independent parts. In the non-limiting variants of FIGS. 1 and 2, the manipulation unit 30 comprises seven suction nozzles 31, the shutter unit 50 comprises seven shutter elements 51, the actuation unit 70 comprises seven displacement actuators 71, and the control unit 92 comprises seven electronic control circuits. It is also possible that all the suction nozzles 31 are identical, that all the shutter elements 51 are identical, that all the displacement actuators 71 are identical, and/or that all the electronic control circuits 92 are identical. Thus, to improve the reading of the figures, all of the numerical references have not been repeated for the seven components 31, 51, 71, 92. Furthermore, in the remainder of the description, the positioning of each component 31, 51, 71, 92 is counted from left to right.

Advantageously, and without this being limiting, the suction nozzles 31 of the manipulation unit 30 may be disposed according to a first matrix distribution defined by at least one first lattice parameter, the shutter elements 51 of the shutter unit 50 may be disposed according to a second matrix distribution defined by at least one second lattice parameter, the displacement actuators 71 of the actuation unit 70 may be disposed according to a third matrix distribution defined by at least one third lattice parameter, and the electronic control circuits 92 are distributed according to a fourth matrix distribution defined by at least one fourth lattice parameter. The first lattice parameter, the second lattice parameter, the third lattice parameter, and the fourth lattice parameter may be integer multiples of each other. However, it is advantageous for the first lattice parameter to be equal to the second lattice parameter, the third lattice parameter, and/or the fourth lattice parameter. Thus, the manipulation system 1 may be used to manipulate micrometric devices 3 disposed according to a matrix distribution on a sampling support 2, for example according to a matrix distribution corresponding to one of the first, second, third, and fourth lattice parameters.

Each suction nozzle 31 of the plurality of suction nozzles 31 comprises a suction channel 33 emerging on the one hand towards the suction chamber 13 at a suction opening 35, and on the other hand at a gripping end 37 intended to be brought into contact with a micrometric device 3 of the plurality of micrometric devices 3. Thus, when the suction chamber 13 is placed in reduced pressure by the pressure reduction device D, the nozzles suctions 31 are able to suck up any element near or in contact with a gripping opening o37 of the gripping end 37. Advantageously, it may be provided that an opening area s37 of the gripping opening 37 of each suction nozzle 31 is strictly less than a contact surface s3 of a micrometric device 3. In this way, when the micrometric device 3 is engaged with the suction nozzle 31, it is maintained by suction on the manipulation unit 30. Generally, a largest dimension of the opening area s37 of the gripping opening 37 is strictly less than 1 mm.

Each shutter element 51 is configured to cooperate with a suction nozzle 31 of the plurality of suction nozzles 31, and to vary between a release configuration in which the shutter element 51 shut off the suction nozzle 31 so as to prevent the gripping of a micrometric device 3 in contact with said gripping end 37, and a gripping configuration in which the shutter element 51 allows a fluid communication between the gripping opening o37 and the suction chamber 13, so as to allow the gripping of a micrometric device 3 in contact with said gripping end 37. It is well understood that when a shutter element 51 is in the gripping configuration, a micrometric device 3 in contact with the gripping end 37 of the gripping nozzle associated with said shutter element 51 is maintained in contact with said gripping end 37 by suction at the gripping opening o37. Said suction being guaranteed by the application of a reduced pressure to the suction chamber 13 by the pressure reduction device D, said reduced pressure then also being applied to each suction nozzle 31 communicating with the suction chamber 13. The shutter element 51 may either completely shut off the suction nozzle 31 in the release configuration, or partially shut off the suction nozzle 31, in the release configuration.

Finally, each displacement actuator 71 is configured to selectively vary at least one of the shutter elements 51 between the gripping configuration and the release configuration. More precisely, each shutter element 51 may be activated individually and/or selectively by a displacement actuator 71. Generally speaking, each displacement actuator 71 is a microelectromechanical system, or MEMS. Each displacement actuator 71 may be associated with an electronic control circuit 92, or may comprise an electronic control circuit 92. Advantageously, the displacement actuators 71 may be configured to selectively vary at least one of the shutter elements 51 between the gripping configuration and the release configuration by electrostatic or magnetic interaction. For example, said at least one displacement actuator 71 may comprise a conductive electrode, or a piezoelectric actuator.

For example, the implementation of an electrostatic interaction may consist in imposing a difference in electric potential between two electrodes, generally disposed opposite each other. The electric field thus creates a force which tends to cause the electrodes to move towards each other. For example, one of the electrodes may be a floating electrode, maintained by a flexible electrical conductor. This floating electrode may then be brought closer to another neighboring electrode, in particular when an electric field is applied between the 2 electrodes.

Alternatively, the implementation of a magnetic interaction may consist in causing the displacement of two objects under the application of a magnetic field between these two objects, and by exploiting the Lorentz force thus generated to carry out this movement.

Generally speaking, each shutter element 51, and/or each displacement actuator 71 is controlled individually by the electronic control circuit 92 with which it is associated. For example, this command may be carried out depending on the matrix distribution of the suction nozzles 31.

As illustrated on the figures, a linking element 56 may be associated with each electronic control circuit 92. This linking element 56 forms a link from the control unit 90 to the manipulation unit 30 between a suction nozzle 31 and the electronic control circuit 92 with which it is associated. Depending on the variants considered, the linking elements 56 may be
mobile linking elements 56 as illustrated on FIGS. 1 and 2; or
fixed linking elements (not represented).

In the second case, the linking elements may correspond to conductive wires configured to ensure an electrical link between the control unit 90 and the manipulation unit 30. More precisely, the linking elements thus allow an electrical connection between an electronic control circuit 92 and a displacement actuator 71. This is particularly advantageous in the case where the electronic control circuit 92 acts as a switch to actuate or not the displacement actuator 71.

The presence of the linking elements 56 allows the relocation or the spacing of the control unit 90 relative to the manipulation unit 30 and facilitates the design of the control unit 90 which may thus be carried out from a full support.

As illustrated on FIGS. 1 and 2, the manipulation system may comprise a guide support 53, disposed between the manipulation unit 30 and the control unit 90, comprising a plurality of guide conduits 55 provided in the guide support 53.

Each guide conduit 55 may be configured to guide a linking element 56 along a guide direction denoted “X1” to directly or indirectly cause a variation of one of the shutter elements 51 between the release configuration and the gripping configuration. Synergistically, the guide support 53 allows to facilitate the design of the manipulation system and allows a reliable guidance of the linking elements 56 in the guide conduits 55, particularly if they are mobile in translation.

In the variant represented on FIG. 1, the shutter elements 51 comprise a flexible membrane comprising a deformable portion configured to be deformed under the indirect action of the displacement actuator 71. Advantageously, a membrane has a thickness strictly smaller than a piston. It is therefore less bulky than a rigid shutter element 51, as may be a piston, it may therefore be more easily integrated into a micrometric system. In addition, a membrane may be carried out with a wide variety of materials chosen depending on integration needs. A membrane therefore has a great ease of integration, as opposed to a piston which induces constraints on its integration. Each linking element 56 may be guided in translation in a guide conduit 55 along the guide direction X1. Each linking element 56 may then cooperate on the one hand with a switching agent 72 which may belong to the control unit 90, and on the other hand with the displacement actuator 71. In the particular case of FIG. 1, the displacement actuators 71 are conductive electrodes which may all have a common potential. In this case, the linking element 56 may be a conductive rod configured to transmit an electrical signal to the displacement actuator 71 either when the linking element 56 is displaced, or, if the linking element is fixed, when the switching agent 72 comes into contact with the linking element 56. In the case where the linking element 56 is mobile, when the switching agent 72 is displaced, it displaces at the same time the displacement of the linking element 56 which then causes the deformation of the flexible membrane of the shutter element 51. In the case where the linking element 56 is fixed, it is the switching agent 72 which is configured to come into contact or not with the linking element 56 to cause the deformation of the flexible membrane of the shutter element 51. Alternatively, the switching agent is a simple electronic circuit breaker incorporated in the electronic control circuit 92 and transmits an electrical signal to the displacement actuator 71 through a fixed linking element, for example an electric wire, connected on one side to the electronic control circuit 92 and on the other side to the displacement actuator 71. These different variants make it possible to simply vary the flexible membrane of the shutter element 51 between the release configuration and the gripping configuration.

According to the variant represented on FIG. 2, at least one of the shutter elements 51 comprises a cooperation portion 52 having a frustoconical shape, said cooperation portion 52 being configured to cooperate with the suction opening 35 of one of the suction nozzles 31, when said at least one shutter element 51 comprising the cooperation portion 52 occupies the release configuration. In this way, it is possible to displace the cooperation portion 52 to shut off the suction nozzle 31, particularly when the suction opening 35 has a circular cross section. In particular, each shutter element 51 may comprise a shutter rod mobile in translation in a guide conduit 55 of the plurality of guide conduits 55, said shutter rod extending between an actuation end 57, typically configured to cooperate with one of the displacement actuators 71, and a shutter end 59 configured to cooperate with the suction opening 35 of one of the suction nozzles 31. Without this being limiting, said shutter rod may be separated into a first rod part comprising the actuating end 57, and a second rod part comprising the shutter end 59, the first rod part and the second rod part being linked by a return device like a spring. In this way, the actuation of the shutter elements 51 is performed at an end opposite to that where the shuttering of the suction nozzles 31 is performed, it is therefore possible to repair or replace independently the manipulation unit 30 and the shutter unit 50. It is possible that the shutter element 51 is fastened to the displacement actuator 71. For example, the shutter element 51 may be in the release configuration in a rest position in which no actuation is implemented by the displacement actuator 71, and may vary in the gripping configuration when the displacement actuator 71 is actuated. Alternatively, the shutter element 51 may be in the gripping configuration in a rest position in which no actuation is implemented by the displacement actuator 71, and may vary in the release configuration when the displacement actuator 71 is actuated. Finally, according to one embodiment, at least one shutter element 51 of the plurality of shutter elements 51 comprises at least one displacement actuator 71 of the plurality of displacement actuators 71. In other words each shutter element 51 may form a displacement actuator 71 and vice versa.

In the case where the shutter unit 50 comprises a guide support 53, each guide conduit 55 may be disposed facing one of the suction nozzles 31, and each linking element 56 may comprise a shutter element 51. Thus, each guide conduit 55 may be configured to guide, for example by translation, the shutter elements 51 along the guide direction X1 when said shutter element 51 varies between the release configuration and the gripping configuration. In this way, it is possible to provide a manipulation system 1 in which the distribution of the guide conduits 55 corresponds to the distribution of the suction nozzles 31.

Each electronic control circuit 92 may comprise one or more transistors. For example, each electronic control circuit 92 may comprise a control transistor configured to be switched so as to authorize or alternatively prevent a passage of electric current, said electric current then inducing a change of configuration between the gripping configuration and the release configuration. The electronic control circuit 92 may also comprise a selection transistor configured to receive row and column instructions from a matrix control system, to switch or not the control transistor depending on the received instructions. Thus, the selection transistor makes it possible to monitor the switching state of the control transistor independently of the other selection transistors disposed on the same line or on the same column.

On the variant represented on FIG. 1, it is the switching agent 72 which may be configured to receive an electrical signal coming from the electronic control circuit 92 with which it is associated to displace the linking element 56 and thus cause the variation of the corresponding shutter element 51 between the gripping configuration and the release configuration depending on said electrical signal. It is thus possible to send electrical signals per line and per column to control selectively and in matrix manner the shutter elements 51 through the linking element 56, and the switching agent 72.

On the variant represented on FIG. 2, each displacement actuator 71 may be configured to receive an electrical signal coming from the electronic control circuit 92 with which it is associated to cause the variation of the corresponding shutter element 51 between the gripping configuration and the release configuration depending on said electrical signal. It is thus possible to send electrical signals per line and per column to control selectively and in matrix manner the displacement actuators 71.

Whatever the variant considered, it is well understood that the linking element 46 makes it possible to relocate the displacement actuators 71 and/or the electronic control circuits 92, on the side opposite that of the suction nozzles 31. It is thus possible to replace the displacement actuators 71, and/or the electronic control circuits 92, independently of the manipulation nozzles 31. In other words, the control unit 90 and the manipulation unit 30 may be replaced or manufactured independently of each other. This is particularly advantageous when manufacturing the manipulation system 1, because it is possible to separately manufacture the manipulation unit 30 which comprises the manipulation nozzles 31 intended to be in contact with the micrometric devices 3, and the control unit 90 which comprises the electronic control circuits 92. Indeed, the manufacturing of the manipulation unit 30 is made complex by the number and the shape of the manipulation nozzles 31 which constitute wearing parts of the manipulation system 1. Conversely, the control unit 90 comprises the electronic control circuits 92 whose manufacturing cost may be higher, but whose wear is slower because they do not come into contact with other parts. The manipulation unit 90 is a solid substrate including the electronic control circuits 92 and the matrix control system with the grid of associated electrical tracks allowing in particular the sending to the electronic control circuits 92 of line and column instructions and electrical power terminals.

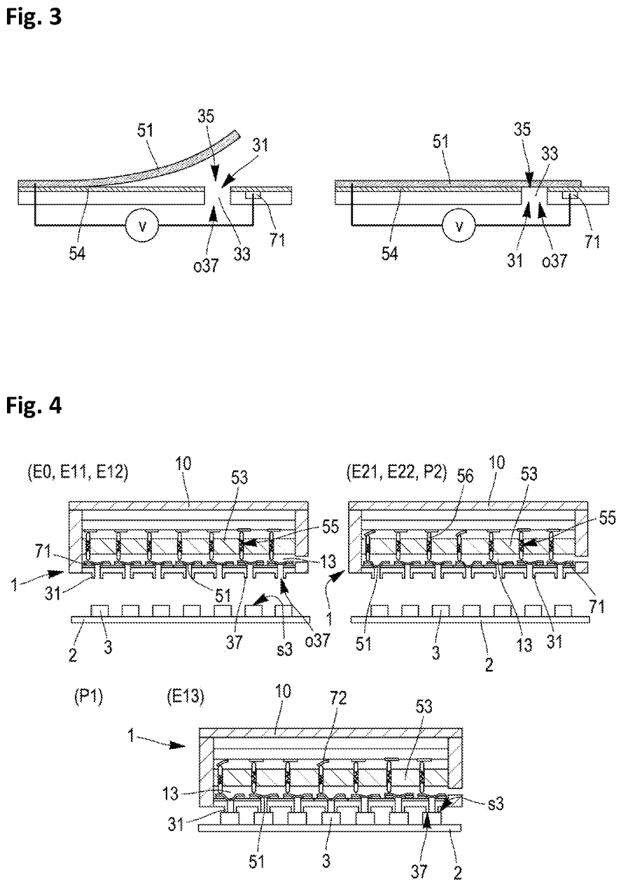

FIG. 3 illustrates another variant in which the shutter element 51 and/or the displacement actuator 71 comprises an elastically deformable blade, configured to vary between two distinct spatial configurations, one (for example a planar configuration) being naturally occupied by elastic return of the material and the other (for example a curved configuration) being temporarily occupied under the action of an external force, typically of a mechanical, electrostatic, thermal, electromagnetic nature or any other method. Alternatively, the curved configuration may be naturally occupied by elastic return of the material, and the planar configuration may be temporarily occupied under the action of an external force, typically of a mechanical, electrostatic, thermal, electromagnetic nature or any other method. For this, the displacement actuator 71 may be disposed under a dielectric layer 54, and may attract or repel the elastically deformable blade forming the shutter element 51 to respectively close or open the suction channel 33 of the nozzle suction 31. It is well understood that such a variant may be simply adapted to the manipulation systems 1 of FIGS. 1 and 2 instead of the suction nozzles 31, the shutter elements 51, and/or the displacement actuators 71.

The arrangements previously described make it possible to propose a manipulation system 1 in which each shutter element 51 may be selectively monitored by a displacement actuator 71 in order to allow or prevent the securing of a micrometric device 3 to a suction nozzle 31. It is thus possible to selectively take a plurality of micrometric devices 3 by the manipulation system 1, for example to perform a selective mass transfer of micrometric devices 3.

As illustrated on FIGS. 4 to 6, the invention also concerns a manipulation method for manipulating micrometric devices 3 where each micrometric device 3 has a contact surface s3. The embodiment of the manipulation method presented on FIGS. 4 to 6 has the steps of the method in a certain order, but it is well understood that those skilled in the art may order the different steps of the method as they wish to manipulate the micrometric devices 3.

According to a non-limiting variant in which one or more of the micrometric devices 3 is an electronic device, the manipulation method may comprise a test step E0 in which each electronic device is electrically tested in order to determine whether it is functional or non-functional. Such a test step E0 may be implemented at the start of the manipulation method, or at other times of the manipulation method.

The manipulation method further comprises a provisioning phase P1 in which a manipulation system 1 of the type of one of those described above is provided. It is well understood that even if the embodiment of the manipulation method described on FIGS. 4 to 6 is with reference to a manipulation system 1 as described in FIG. 1, it is entirely possible to adapt it to a manipulation system as described in FIG. 2 or comprising the elements described in FIG. 3. For example such a manipulation system may be provided during a step E11 of providing the manipulation system 1.

The provisioning phase P1 may also include a step E12 of providing the plurality of micrometric devices 3 disposed on the sampling substrate 2. It may then be planned to implement a contacting step E13, in which the gripping end 37 of at least one of the suction nozzles 31 is brought into contact with the contact surface s3 of at least one of the micrometric devices 3. As a result, at the end of the provisioning phase P1, the gripping end 37 of at least one of the suction nozzles 31 is in contact with the contact surface s3 of at least one of said micrometric devices 3. Thus, the provisioning phase P1 may be implemented in order to take one or more micrometric devices 3 from the surface of a sampling substrate 2, for example in order to transfer them.

The manipulation method also comprises an actuation phase P2 in which at least one of the displacement actuators 71 of the actuation unit 70 of the manipulation system 1 is actuated, so as to cause the variation of at least one of the shutter elements 51 cooperating with one of the suction nozzles 31 in contact with one of the micrometric devices 3 between the gripping configuration and the release configuration, the actuation phase P2 then comprising, for at least one of the configuration-varying shutter elements 51, chosen from said at least one of the shutter elements 51:
a securing step E21 in which the micrometric device 3 is secured to the suction nozzle 31 when said configuration-varying shutter element 51 is varied to the gripping configuration, or
a separation step E22 in which the micrometric device 3 is separated from the suction nozzle 31 when said configuration-varying shutter element 51 is varied to the release configuration.

It is therefore well understood that the securing step E21 may be implemented when a shutter element 51 is varied to, or is in the gripping configuration. It is also well understood that the separation step E22 may be implemented when a shutter element 51 is varied to, or is in the release configuration.

As represented on FIG. 4, the actuation phase P2 may also comprise the variation of at least one of the shutter elements 51 cooperating with one of the suction nozzles 31 from the gripping configuration to the release configuration, or from the release configuration to the gripping configuration before bringing the gripping end 37 into contact with the contact surface s3 of the micrometric device. This actuation phase P2 may be implemented by a magnetic or electrostatic actuation of at least one of the displacement actuators 71, by a thermal or mechanical actuation of the at least one displacement actuator 71, or all other way. In this way, depending on the destination of the micrometric devices 3 it is possible to adapt the actuation phase P2.

Whatever the variant considered, the actuation phase P2 may be implemented depending on the result of the test step E0. For example, the actuation phase P2 may be applied selectively so as to implement the securing step E21 for the functional electronic devices 3, and so as to implement the separation step E22 for the non-functional electronic devices. In this way, it is possible to pick up and possibly displace the functional devices, for example to transfer them to a final receiving support 4. Alternatively, the actuation phase P2 may be applied selectively so as to implement the separation step E22 for the functional electronic devices 3, and so as to implement the securing step E21 for the non-functional electronic devices. In this way, it is possible to pick up and possibly displace the non-functional devices, for example to remove them from a final receiving substrate, or from a sampling substrate 2 before performing a non-selective mass transfer of the functional devices remaining on the surface of the sampling substrate 2. On the example represented on FIG. 4, the test step EO may have revealed that the electronic devices 3 disposed in the first and fourth positions were defective. Consequently, the actuation phase P2 is implemented to vary the shutter elements 51 in the first and fourth positions in the release configuration.

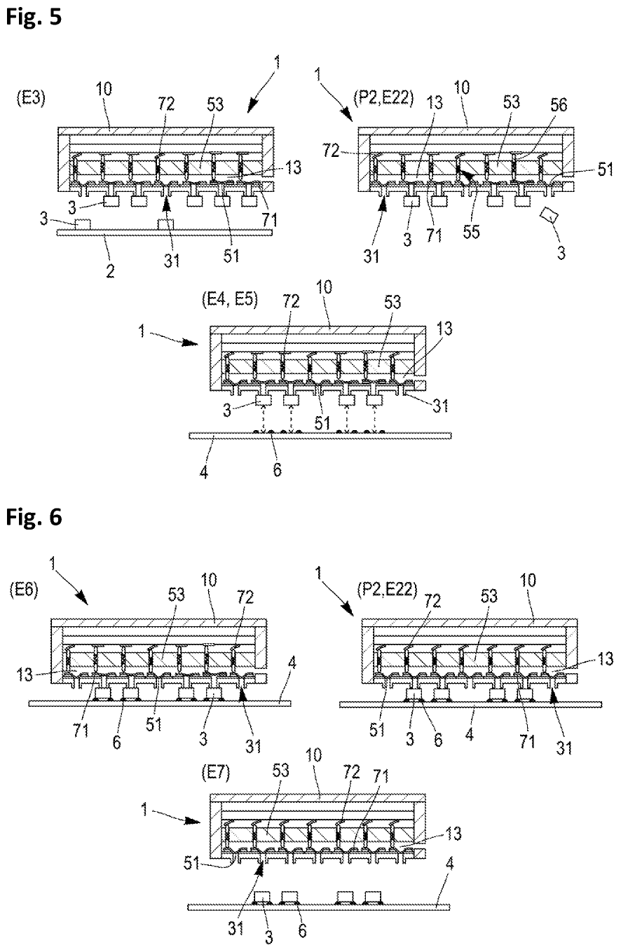

With reference to FIG. 5, the manipulation method comprises an unhooking step E3 implemented after the actuation phase P2, in which the manipulation system 1 is moved away from the sampling substrate 2, so as to unhook, relative to the sampling substrate 2, the micrometric devices 3 secured to the suction nozzles 31 during the securing step E21. For example, the unhooking step E3 is implemented by mechanical traction. In this way it is possible to selectively collect the micrometric devices 3 to be manipulated from the surface of the sampling substrate 2. On the embodiment of FIG. 5, only the micrometric devices 3 disposed between the first and fourth positions are not secured to the manipulation system 1, because the shutter elements 51 placed in the first and fourth positions are in the release configuration. Consequently, the suction at the suction nozzles 31 located in the first and fourth positions is not sufficient to allow detachment of the micrometric devices 3 in contact with these suction nozzles 31, they therefore remain on the surface of the sampling support 2.

As illustrated on FIG. 5, it is possible to implement the actuation phase P2 again. In particular, FIG. 5 shows that a separation step E22 is implemented at the suction nozzle 31 located in the seventh position. During this separation step E22, the shutter element 51 varies from the gripping configuration to the release configuration. The corresponding micrometric device 3 is then separated from the suction nozzle 31, and the micrometric device 3 in the seventh position is then detached from the manipulation system 1. This separation step E22 may for example have been implemented following a second test step E0 having revealed the non-functionality of the electronic device 3 disposed in the seventh position.

Thus, in general, the actuation phase P2 is implemented for the non-functional electronic devices 3, or to release functional electronic devices 3 which we do not wish to transfer. In this way, it is possible to pick up and possibly displace the functional electronic devices 3, for example to transfer them to a final receiving support 4

For this, the manipulation method may comprise a transfer step E4 implemented after the provisioning phase P1, in which the manipulation system 1 is placed opposite a receiving support 4 capable of receiving at least one of the manipulated micrometric devices 3. In this way it is possible to place the micrometric devices 3 opposite a receiving surface of the receiving support 4 which can be the final destination support of the micrometric devices 3. In the case where the micrometric devices 3 are electronic or optoelectronic devices, the transfer step E4 may be implemented so as to place the optoelectronic devices opposite a screen substrate.

Advantageously, the manipulation method may comprise an alignment step E5 in which the manipulation system 1 is aligned with the receiving support 4. In this way, it is possible to precisely determine the location at which each micrometric device 3 may be deposited on the receiving support 4. For example, if the micrometric devices 3 are electronic or optoelectronic devices, the alignment step E5 may be implemented so as to align each electronic device 3 with electrically conductive elements 6 disposed on the receiving support 4 and configured to supply the electronic devices 3 with electrical energy.

Then, the manipulation method may comprise a deposition step E6, implemented after the transfer step E4, in which the manipulation system 1 is brought close to the receiving support 4, so as to bring manipulated micrometric devices 3 into contact directly or indirectly, with said final receiving support 4. For example, each electronic device 3 is brought into contact with the electrically conductive elements 6.

As illustrated in FIG. 3, another actuation phase P2 may be implemented. In particular, a separation step E22 may be carried out to actuate all of the displacement actuators 71 of the manipulation system 1, so as to cause the passage of all the shutter elements 51 from the gripping configuration to the release configuration, to cause the remaining micrometric devices 3 to detach.

Finally, the manipulation method may comprise a removal step E7, implemented after the deposition step E6, in which the manipulation system 1 is moved away from the receiving support 4.

The arrangements previously described make it possible to propose a manipulation method in which micrometric devices 3 may be attached or detached from the manipulation system 1 by a selective actuation of the displacement actuators 71. This makes it possible to selectively manipulate a large quantity of micrometric devices 3, by a single method step, and through a single manipulation system 1.

1-20. (Canceled)

21. A manipulation system intended to manipulate a plurality of micrometric devices, the manipulation system comprising:
a main body internally delimiting a suction chamber, said suction chamber being intended to be in fluid communication with a pressure reduction device;
a manipulation unit comprising a plurality of suction nozzles, each suction nozzle of the plurality of suction nozzles comprising a suction channel emerging on the one hand towards the suction chamber at a suction opening, and on the other hand at a gripping end intended to be brought into contact with a micrometric device of the plurality of micrometric devices;
a shutter unit comprising a plurality of shutter elements, each shutter element being configured to cooperate with a suction nozzle of the plurality of suction nozzles, and being configured to vary between a release configuration in which the shutter element shuts off the suction nozzle so as to prevent the gripping of a micrometric device in contact with said gripping end, and a gripping configuration in which the shutter element allows a fluid communication between a gripping opening of the gripping end and the suction chamber, so as to allow the gripping of a micrometric device in contact with said gripping end, the shutter unit further comprising an actuation unit comprising a plurality of displacement actuators, wherein each displacement actuator is configured to selectively vary at least one of the shutter elements between the gripping configuration and the release configuration.

22. The manipulation system according to claim 21, wherein an opening area of the gripping opening of each suction nozzle is strictly less than a contact surface of a micrometric device intended to be manipulated by the manipulation system.

23. The manipulation system according to claim 21, wherein at least one shutter element comprises a flexible membrane.

24. The manipulation system according to claim 21, wherein at least one of the shutter elements comprises a cooperation portion having a frustoconical shape, said cooperation portion being configured to cooperate with the suction opening of one of the suction nozzles, when said at least one shutter element comprising the cooperation portion occupies the release configuration.

25. The manipulation system according to claim 21, wherein at least one of the displacement actuators is configured to selectively vary at least one of the shutter elements between the gripping configuration and the release configuration by electrostatic or magnetic interaction.

26. The manipulation system according to claim 21, comprising a guide support comprising a plurality of guide conduits provided in the guide support, each guide conduit being configured to guide a linking element along a guide direction, to directly or indirectly cause a variation of one of the shutter elements between the release configuration and the gripping configuration.

27. The manipulation system according to claim 26, wherein the shutter element comprises the linking element, each guide conduit then being disposed facing one of the suction nozzles, and configured to guide the shutter element along the guide direction when said shutter element varies between the release configuration and the gripping configuration.

28. The manipulation system according to claim 27, wherein each shutter element extends between an actuation end, and a shutter end configured to cooperate with the suction opening of one of the suction nozzles.

29. The manipulation system according to claim 27, wherein the linking element extends between a monitoring end configured to cooperate with an electronic control circuit, and a control end configured to cooperate with a displacement actuator.

30. The manipulation system according to claim 21, wherein:
the suction nozzles of the manipulation unit are disposed according to a first matrix distribution defined by at least one first lattice parameter,
the shutter elements of the shutter unit are disposed according to a second matrix distribution defined by at least one second lattice parameter;
one of the first lattice parameter and of the second lattice parameter being an integer multiple of the other.

31. The manipulation system according to claim 30, wherein the displacement actuators are disposed according to a third matrix distribution defined by at least one third lattice parameter which is an integer multiple of the second lattice parameter, the manipulation system further comprising a control unit comprising a plurality of electronic control circuits distributed according to a fourth matrix distribution defined by at least one fourth lattice parameter which is an integer multiple of the third lattice parameter, each displacement actuator being associated with an electronic control circuit and configured to receive an electrical signal coming from the electronic control circuit with which it is associated to cause the variation of said shutter element between the gripping configuration and the release configuration depending on said electrical signal.

32. The manipulation system according to claim 21, comprising a control unit comprising a plurality of electronic control circuits, said control unit being offset relative to the manipulation unit.

33. The manipulation system according to claim 32, wherein a linking element is associated with each electronic control circuit, said linking element forming a link from the control unit to the manipulation unit between a suction nozzle and the electronic control circuit to which it is associated.

34. A method for manipulating a plurality of micrometric devices where each micrometric device has a contact surface, the manipulation method comprising:
a provisioning phase in which a manipulation system according to claim 21 is provided, the gripping end of at least one of the suction nozzles being in contact with the contact surface of at least one of said micrometric devices;
an actuation phase in which at least one of the shutter elements cooperating with one of the suction nozzles in contact with one of the micrometric devices is varied between the gripping configuration and the release configuration, the actuation phase then comprising, for at least one of the configuration-varying shutter elements, chosen from said at least one of the shutter elements:
a securing step in which the micrometric device is secured to the suction nozzle when said configuration-varying shutter element is varied to the gripping configuration, or
a separation step in which the micrometric device is separated from the suction nozzle when said configuration-varying shutter element is varied to the release configuration.

35. The manipulation method according to claim 34, wherein the provisioning phase comprises:
a step of providing the manipulation system;
a step of providing the plurality of micrometric devices disposed on a sampling substrate;
a contacting step, in which the gripping end of at least one of the suction nozzles is brought into contact with the contact surface of at least one of the micrometric devices.

36. The manipulation method according to claim 35, comprising an unhooking step implemented after the actuation phase, in which the manipulation system is moved away from the sampling substrate, so as to unhook, relative to the sampling substrate, the micrometric devices secured to suction nozzles during the securing step.

37. The manipulation method according to claim 34, wherein the actuation phase is implemented when at least one of the displacement actuators of the actuation unit is actuated, so as to cause the variation of at least one of the shutter elements cooperating with one of the suction nozzles in contact with one of the micrometric devices between the gripping configuration and the release configuration.

38. The manipulation method according to claim 37, wherein the actuation phase is implemented by a magnetic or electrostatic actuation of at least one of the displacement actuators.

39. The manipulation method according to claim 34, comprising a transfer step implemented after the provisioning phase, in which the manipulation system is placed opposite a receiving support capable of receiving at least one of the manipulated micrometric devices.

40. The manipulation method according to claim 34, wherein at least one of the micrometric devices to be manipulated is an electronic device, the manipulation method comprising a test step in which said at least one electronic device is electrically tested in order to determine whether it is functional or non-functional, the actuation phase then being implemented depending on the result of the test step.
